(19) United States
(12) Patent Application Publication
(10) Pub. No.: US 2022/0158585 A1
(43) Pub. Date: May 19, 2022

(54) COLORED PHOTOVOLTAIC ROOF TILES

(71) Applicant: Tesla, Inc., Palo Alto, CA (US)

(72) Inventors: Milan PADILLA, Mountain View, CA (US); Bradley VERBON, Alameda, CA (US); Li ZHANG, Campbell, CA (US); Christian HONEKER, Fremont, CA (US)

(21) Appl. No.: 17/523,724

(22) Filed: Nov. 10, 2021

Related U.S. Application Data
(60) Provisional application No. 63/115,481, filed on Nov. 18, 2020.

(51) Int. Cl. H02S 20/25; H01L 31/048; H01L 31/05

(52) U.S. Cl. CPC H02S 20/25; H01L 31/0508; H01L 31/0481

(57) ABSTRACT

One embodiment can provide a photovoltaic roof tile module. The photovoltaic roof tile module can include a front encapsulant layer and a back encapsulant layer where both the front and back encapsulant layers include different pigments. The front encapsulant layer can include a small amount of pigment that absorbs and scatters particular frequencies of visible light to give the photovoltaic roof tile a desired color. The small amount of pigment does not absorb or scatter a significant amount of infrared light. Two or more photovoltaic roof tiles can be combined to form a photovoltaic module. The two or more photovoltaic roof tiles can have different concentrations of pigment in the front encapsulant layer to give the photovoltaic module a small amount of color variation.

### CROSS-REFERENCE TO RELATED APPLICATIONS

This application claims priority to U.S. Provisional Patent Application 63/115,481, entitled, “COLORED PHOTOVOLTAIC ROOF TILES,” filed Nov. 18, 2020, the content of which is hereby incorporated by reference in its entirety and for all purposes.

### BACKGROUND

### Field

This disclosure is generally related to photovoltaic roof tiles. More specifically, this disclosure describes infusing one or more layers of encapsulant surrounding solar cells of a photovoltaic roof tile with pigment to alter a cosmetic appearance of a photovoltaic roof tile.

### Related Art

In residential and commercial solar energy installations, a building's roof typically is installed with photovoltaic (PV) modules, also called PV or solar panels, that can include a two-dimensional array (e.g., 6×12) of solar cells. A PV roof tile (or solar roof tile) can be a particular type of PV module offering weather protection for the home and a pleasing aesthetic appearance, while also functioning as a PV module to convert solar energy to electricity. The PV roof tile can be shaped like a conventional roof tile and can include one or more solar cells encapsulated between a front cover and a back cover, but typically encloses fewer solar cells than a conventional solar panel.

The front and back covers can be fortified glass or other material that can protect the PV cells from the weather elements. Note that a typical roof tile may have a dimension of 15 in×8 in =120 in²=774 cm², and a typical solar cell may have a dimension of 6 in×6 in=36 in²=232 cm². Similar to a conventional PV panel, the PV roof tile can include an encapsulating layer, such as an organic polymer. A lamination process can seal the solar cells between the front and back covers. Unfortunately, PV roof tiles are not generally available in the number of colors a consumer would generally be able to choose from when adding a conventional roof top. For this reasons, methods and apparatus for offering PV roof tiles in a variety of different colors are desirable.

### SUMMARY

One embodiment can provide a photovoltaic roof tile module. The photovoltaic roof tile module can include a plurality of photovoltaic roof tiles mechanically and electrically coupled to each other.

A respective photovoltaic roof tile module is disclosed and can include a photovoltaic roof tile that includes a front glass cover; a front encapsulant layer doped with a first pigment; a back encapsulant layer doped with a second pigment different than the first pigment that corresponds to a color of the plurality of solar cells; and a plurality of solar cells positioned between the front and back encapsulant layers.

A photovoltaic roof tile is disclosed and can include a front glass cover; a front encapsulant layer doped with a first pigment; a plurality of solar cells; and a back encapsulant layer doped with a second pigment different than the first pigment that corresponds to a color of the plurality of solar cells.

In some embodiments, the front encapsulant layer of a first photovoltaic roof tile has five to ten percent more of the first pigment than the front encapsulant layer of a second photovoltaic roof tile adjacent to the first photovoltaic roof tile. A “solar cell” or “cell” is a photovoltaic structure capable of converting light into electricity. A cell may have any size and any shape, and may be created from a variety of materials. For example, a solar cell may be a photovoltaic structure fabricated on a silicon wafer or one or more thin films on a substrate material (e.g., glass, plastic, or any other material capable of supporting the photovoltaic structure), or a combination thereof.

A “solar cell strip,” “photovoltaic strip,” “smaller cell,” or “strip” is a portion or segment of a photovoltaic structure, such as a solar cell. A photovoltaic structure may be divided into a number of strips. A strip may have any shape and any size. The width and length of a strip may be the same or different from each other. Strips may be formed by further dividing a previously divided strip.

“Finger lines,” “finger electrodes,” and “fingers” refer to elongated, electrically conductive (e.g., metallic) electrodes of a photovoltaic structure for collecting carriers.

“Busbar,” “bus line,” or “bus electrode” refer to elongated, electrically conductive (e.g., metallic) electrodes of a photovoltaic structure for aggregating current collected by two or more finger lines. A busbar is usually wider than a finger line, and can be deposited or otherwise positioned anywhere on or within the photovoltaic structure. A single photovoltaic structure may have one or more busbars.

A “photovoltaic structure” can refer to a solar cell, a segment, or a solar cell strip. A photovoltaic structure is not limited to a device fabricated by a particular method. For example, a photovoltaic structure can be a crystalline silicon-based solar cell, a thin film solar cell, an amorphous silicon-based solar cell, a polycrystalline silicon-based solar cell, or a strip thereof.

### BRIEF DESCRIPTION OF THE FIGURES

FIG. 1 shows an exemplary configuration of PV roof tiles on a house.

FIG. 2 shows a perspective front view of an exemplary photovoltaic roof tile, according to an embodiment.

FIG. 3A shows an exemplary configuration of a multi-tile module, according to one embodiment.

FIG. 3B shows a cross-section of an exemplary multi-tile module, according to one embodiment.

FIG. 4A illustrates a serial connection among three adjacent cascaded photovoltaic strips, according to one embodiment.

FIG. 4B illustrates a side view of the string of cascaded strips, according to one embodiment.

FIG. 4C illustrates an exemplary solar roof tile, according to one embodiment.

FIG. 5A shows a top view of an exemplary multi-tile module, according to one embodiment.

FIG. 5B shows a top view of another exemplary solar roof tile, according to one embodiment.

FIG. 6 shows a partial view of a roof having a number of solar roof tiles and passive roof tiles.

FIG. 7A shows an exploded view of an exemplary photovoltaic roof tile, according to one embodiment.

FIGS. 7B-7D show how a concentration of pigment within a front encapsulant layer can allow variance in the cosmetic appearance of photovoltaic roof tiles.

FIGS. 8A-8C show side views of exemplary photovoltaic roof tiles, according to some embodiments.

FIG. 9 shows a flow chart illustrating a manufacturing process for a photovoltaic roof tile.

FIG. 10 shows an image of encapsulant material mixed with first and second pigments.

FIG. 11 shows an image of a photovoltaic roof tile module that incorporates a front encapsulant layer doped with a first pigment and a second pigment.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the disclosed system is not limited to the embodiments shown, but is to be accorded the widest scope consistent with the principles and features disclosed herein.

### Overview

Embodiments of the invention solve at least the technical problem of improving aesthetics of solar roof tiles at a low cost. A solar roof tile (or PV roof tile) can include a number of solar cells sandwiched between a front glass cover and a back cover. Due to manufacturing imperfections, the solar cells, and hence, the PV roof tiles, can have inherent color variations. Moreover, PV roof tiles can also have different color appearances under different lighting and/or at different viewing angles. To mitigate the color contrast, either within a PV roof tile or between PV roof tiles and non-PV roof tiles, in some embodiments, a robust color-management scheme is adopted while manufacturing the tiles. First, to reduce the color contrast within a PV roof tile, the PV roof tile can encapsulate mono or polycrystalline-Si-based photovoltaic structures. By controlling the size and pattern of the surface texture of the mono or polycrystalline-Si-based photovoltaic structures, one can reduce the anisotropic optics, sometimes described as “glow” of the photovoltaic structures. While keeping the front cover of the roof tile transparent, the back surface of the back cover can be coated with a layer of paint that matches the color of the textured surface of the photovoltaic structures to reduce the color contrast within the PV roof tile. A similar paint layer can also be deposited onto the back surface of the non-PV roof tiles. As a result, the color appearance of the PV and non-PV roof tiles can be quite similar. Alternatively, a layer of encapsulant positioned behind the photovoltaic structures can be colored with pigment to match the color of the photovoltaic structures in order to reduce color contrast on the perimeters of the PV roof tile. Moreover, when assembling the PV roof tiles, the embedded photovoltaic structures are fed into the production line following a predetermined color pattern such that a majority of PV roof tiles contains solar cells of a similar color and PV roof tiles of different colors are evenly or randomly mixed to prevent clustering of colors on a roof.

In some embodiments, one can also create PV roof tiles as well as non-PV roof tiles having significantly different surface colors by selectively treating the front encapsulant layer with pigment. There are different ways of treating the front encapsulant layer. By varying an amount of pigment within the front encapsulant layer in a series of adjacent roof tiles a roof top can have a non-uniform appearance.

In some embodiments, a rear encapsulant layer can be treated with pigment that matches a color of the photovoltaic structures. In this configuration, an overall color of a respective photovoltaic roof tile can be determined by colors of both the front and rear encapsulant layers.

A “solar cell” or “cell” is a photovoltaic structure capable of converting light into electricity. A cell may have any size and any shape, and may be created from a variety of materials. For example, a solar cell may be a photovoltaic structure fabricated on a silicon wafer or one or more thin films on a substrate material (e.g., glass, plastic, or any other material capable of supporting the photovoltaic structure), or a combination thereof.

A “solar cell strip,” “photovoltaic strip,” “smaller cell,” or “strip” is a portion or segment of a photovoltaic structure, such as a solar cell. A photovoltaic structure may be divided into a number of strips. A strip may have any shape and any size. The width and length of a strip may be the same or different from each other. Strips may be formed by further dividing a previously divided strip.

“Finger lines,” “finger electrodes,” and “fingers” refer to elongated, electrically conductive (e.g., metallic) electrodes of a photovoltaic structure for collecting carriers.

“Busbar,” “bus line,” or “bus electrode” refer to elongated, electrically conductive (e.g., metallic) electrodes of a photovoltaic structure for aggregating current collected by two or more finger lines. A busbar is usually wider than a finger line, and can be deposited or otherwise positioned anywhere on or within the photovoltaic structure. A single photovoltaic structure may have one or more busbars.

A “photovoltaic structure” can refer to a solar cell, a segment, or a solar cell strip. A photovoltaic structure is not limited to a device fabricated by a particular method. For example, a photovoltaic structure can be a crystalline silicon-based solar cell, a thin film solar cell, an amorphous silicon-based solar cell, a polycrystalline silicon-based solar cell, or a strip thereof.

### PV Roof Tiles and Multi-Tile Modules

A PV roof tile (or solar roof tile) is a type of PV module shaped like a roof tile and typically enclosing fewer solar cells than a conventional solar panel. Note that such PV roof tiles can function as both PV cells and roof tiles at the same time. In some embodiments, the system disclosed herein can be applied to PV roof tiles and/or other types of PV module.

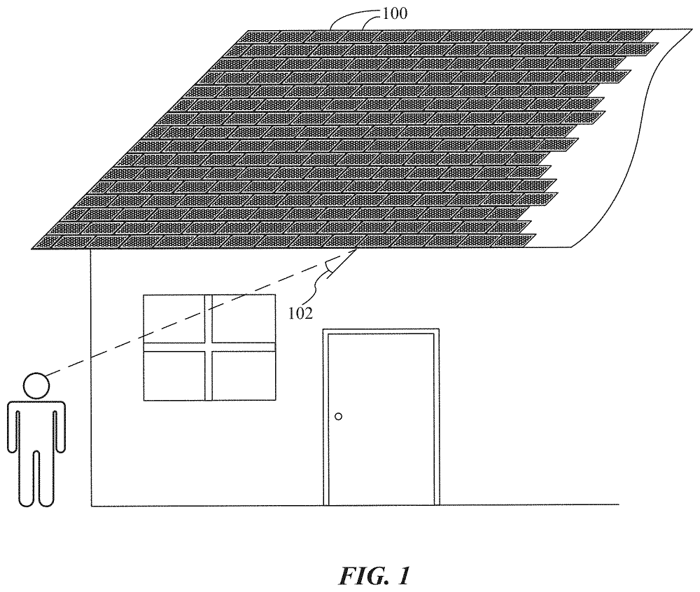

FIG. 1 shows an exemplary configuration of PV roof tiles on a house. PV roof tiles 100 can be installed on a house like conventional roof tiles or shingles. Particularly, a PV roof tile can be placed with other tiles in such a way as to prevent water from entering the building.

A PV roof tile can enclose multiple solar cells or PV structures, and a respective PV structure can include one or more electrodes, such as busbars and finger lines. The PV structures within a PV roof tile can be electrically and, optionally, mechanically coupled to each other. For example, multiple PV structures can be electrically coupled together by a metallic tab, via their respective busbars, to create serial or parallel connections. Moreover, electrical connections can be made between two adjacent tiles, so that a number of PV roof tiles can jointly provide electrical power. Cosmetic features of the PV roof tiles can allow the PV roof tiles to blend in and look the same as non-PV roof tiles. In some embodiments the cosmetic features can be designed to operate ideally when viewed from an angle 102.

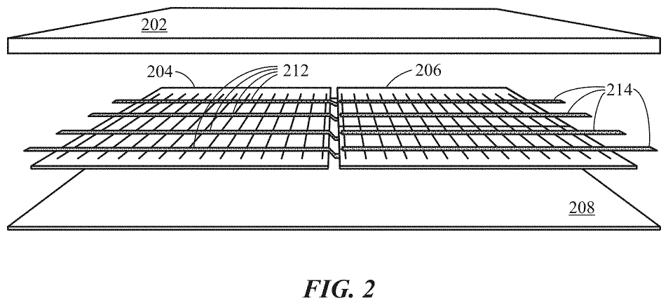

FIG. 2 shows a perspective view of an exemplary photovoltaic roof tile, according to an embodiment. Solar cells 204 and 206 can be hermetically sealed between top glass cover 202 and backsheet 208, which jointly can protect the solar cells from various weather elements. In the example shown in FIG. 2, metallic tabbing strips 212 can be in contact with the front-side electrodes of solar cell 204 and extend beyond the left edge of glass 202, thereby serving as contact electrodes of a first polarity of the PV roof tile. Tabbing strips 212 can also be in contact with the back of solar cell 206, creating a serial connection between solar cell 204 and solar cell 206. On the other hand, tabbing strips 214 can be in contact with front-side electrodes of solar cell 206 and extend beyond the right edge of glass cover 202, serving as contact electrodes of a second polarity of the PV roof tile. In some embodiments, backsheet 208 can be a standard backsheet formed from one or more layers of polymer such as, e.g., fluoropolymers or combinations of PET and EVA layers. Alternatively backsheet 208 can take the form of a back glass cover.

In some embodiments, array of solar cells 204 and 206 can be encapsulated between top glass cover 202 and back cover 208. A top encapsulant layer, which can be based on a polymer, can be used to seal top glass cover 202 to array of solar cells 204/206. Specifically, the top encapsulant layer may include polyvinyl butyral (PVB), thermoplastic polyolefin (TPO), ethylene vinyl acetate (EVA), or N,N′-diphenyl-N,N′-bis(3-methylphenyl)-1,1′-diphenyl-4,4′-diamine (TPD). Similarly, a lower encapsulant layer, which can be based on a similar material, can be used to seal the array of solar cells to back cover 208. A PV roof tile can also contain other optional layers, such as an optical filter or coating layer or a layer of nanoparticles for providing desired color appearances. In the example of FIG. 2, module or roof tile 300 can also contains an optical filter layer between the array of solar cells and front glass cover 202.

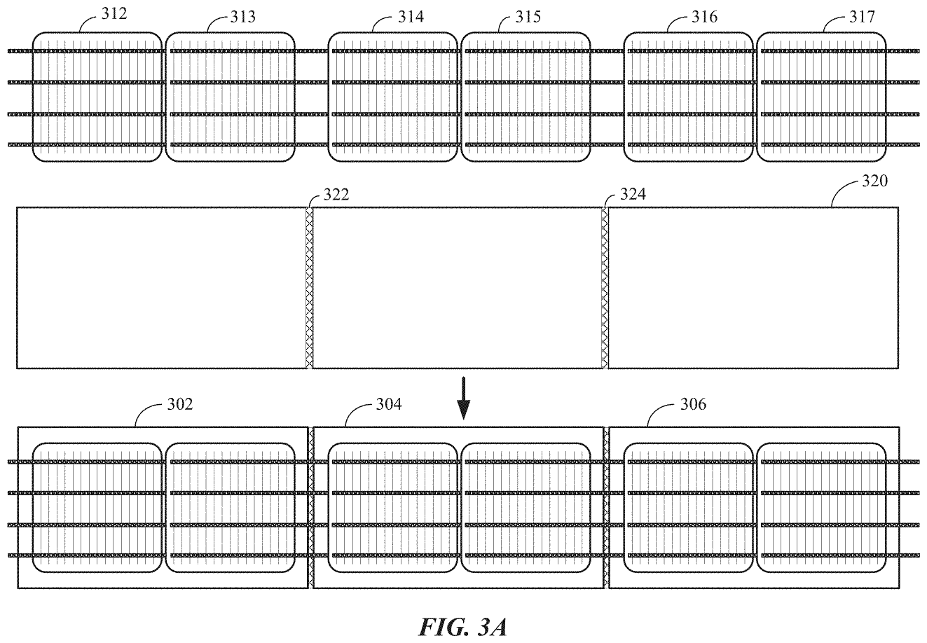

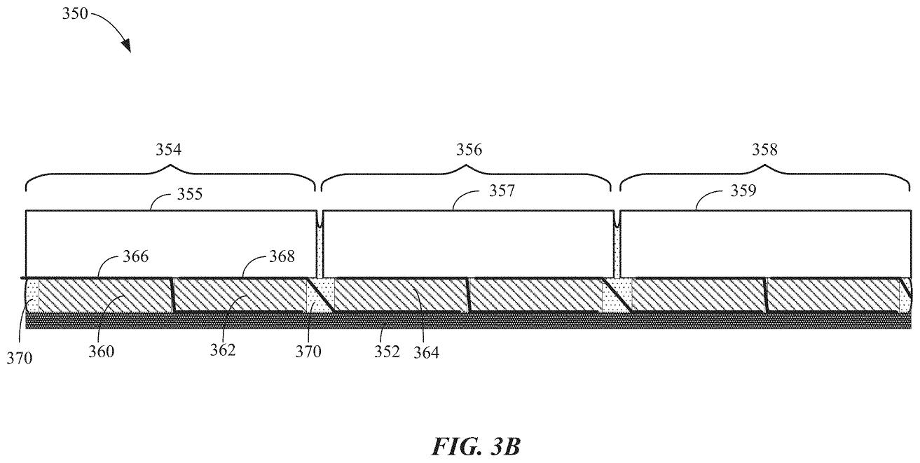

To facilitate more scalable production and easier installation, multiple photovoltaic roof tiles can be fabricated together, while the tiles are linked in a rigid or semi-rigid way. FIG. 3A illustrates an exemplary configuration of a multi-tile module, according to one embodiment. In this example, three PV roof tiles 302, 304, and 306 can be manufactured establishing a semi-rigid couplings 322 and 324 between adjacent tiles. Prefabricating multiple tiles into a rigid or semi-rigid multi-tile module can significantly reduce the complexity in roof installation, because the tiles within the module have been connected with the tabbing strips. Note that the number of tiles included in each multi-tile module can be more or fewer than what is shown in FIG. 3A.

FIG. 3B illustrates a cross-section of an exemplary multi-tile module, according to one embodiment. In this example, multi-tile module 350 can include photovoltaic roof tiles 354, 356, and 358. These tiles can share common backsheet 352, and have three individual glass covers 355, 357, and 359, respectively. Each tile can encapsulate two solar cells. For example, tile 354 can include solar cells 360 and 362 encapsulated between backsheet 352 and glass cover 355. Tabbing strips can be used to provide electrical coupling within each tile and between adjacent tiles. For example, tabbing strip 366 can couple the front electrode of solar cell 360 to the back electrode of solar cell 362, creating a serial connection between these two cells. Similarly, tabbing strip 368 can couple the front electrode of cell 362 to the back electrode of cell 364, creating a serial connection between tile 354 and tile 356.

Gaps 322 and 324 between adjacent PV tiles can be filled with encapsulant, protecting tabbing strips interconnecting the two adjacent tiles from the weather elements. For example, encapsulant 370 fills the gap between tiles 354 and 356, protecting tabbing strip 368 from weather elements. Furthermore, the three glass covers, backsheet 352, and the encapsulant together form a semi-rigid construction for multi-tile module 350. This semi-rigid construction can facilitate easier installation while providing a certain degree of flexibility among the tiles.

In addition to the examples shown in FIGS. 3A and 3B, a PV tile may include different forms of photovoltaic structures. For example, in order to reduce internal resistance, each square solar cell shown in FIG. 3A can be divided into multiple (e.g., three) smaller strips, each having edge busbars of different polarities on its two opposite edges. The edge busbars allow the strips to be cascaded one by one to form a serially connected string.

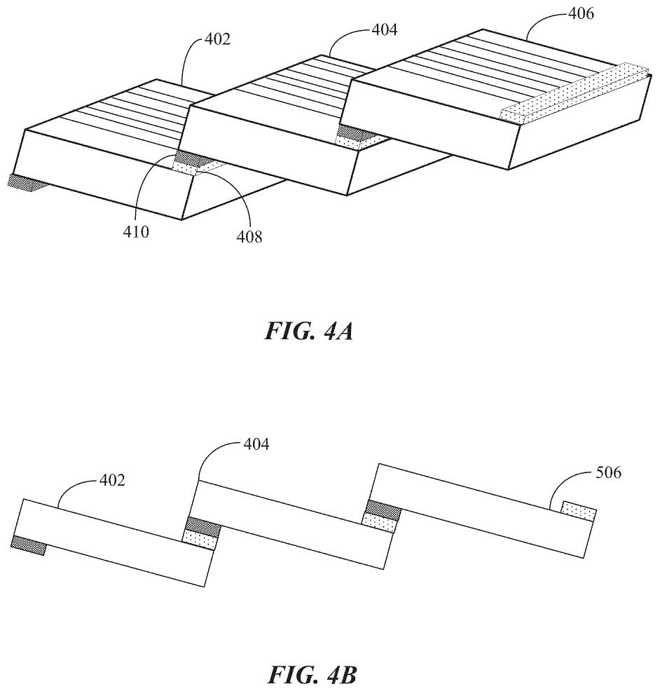

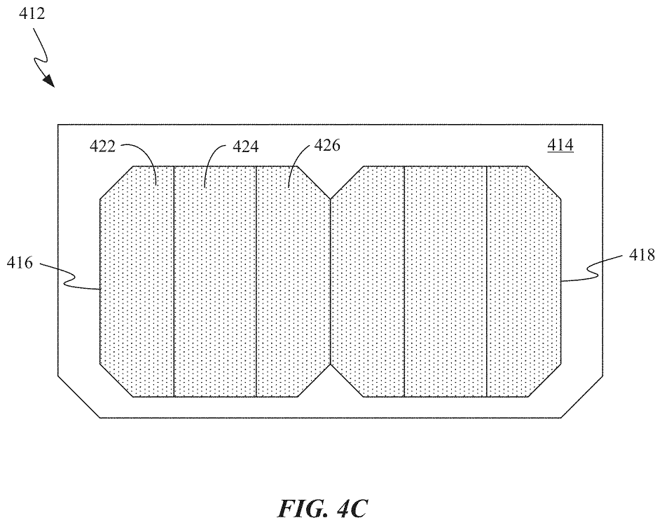

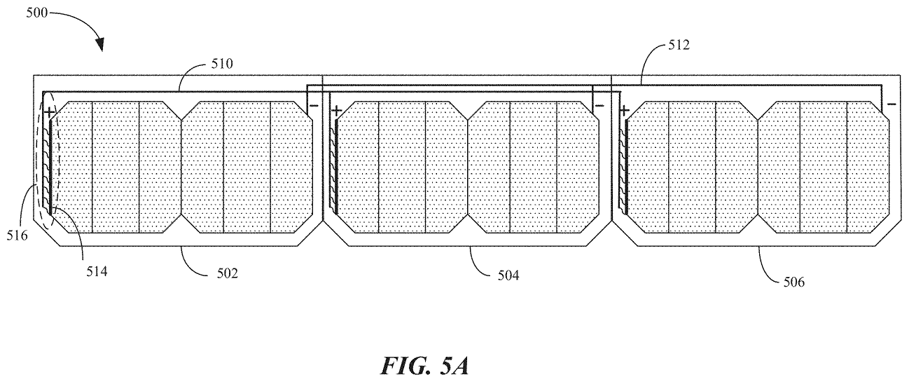

FIG. 4A illustrates a serial connection among three adjacent cascaded photovoltaic strips, according to one embodiment. In FIG. 4A, strips 502, 504, and 506 are stacked in such a way that strip 504 partially underlaps adjacent strip 506 to its right, and overlaps strip 502 to its left. The resulting string of strips forms a cascaded pattern similar to roof shingles. Strips 502 and 504 are electrically coupled in series via edge busbar 508 at the top surface of strip 502 and edge busbar 510 at the bottom surface of strip 504. Strips 502 and 504 can be arranged in such a way that bottom edge busbar 510 is above and in direct contact with top edge busbar 508. The coupling between strips 504 and 506 can be similar.

FIG. 4B illustrates a side view of the string of cascaded strips, according to one embodiment. In the example shown in FIGS. 4A and 4B, the strips can be segments of a six-inch square or pseudo-square solar cell, with each strip having a dimension of approximately two inches by six inches. To reduce shading, the overlapping between adjacent strips should be kept as small as possible. Therefore, in the example shown in FIGS. 4A and 4B, the single busbars (both at the top and the bottom surfaces) can be placed at or near the very edge of the strip. The same cascaded pattern can extend along multiple strips to form a serially connected string, and a number of strings can be coupled in series or parallel.

FIG. 4C illustrates an exemplary solar roof tile, according to one embodiment. A solar roof tile 412 includes top glass cover 414 and solar cells 516 and 518. The bottom cover (e.g., backsheet) of solar roof tile 412 is out of view in FIG. 4C. Solar cells 416 and 418 can be conventional square or pseudo-square solar cells, such as six-inch solar cells. In some embodiments, solar cells 416 and 418 can each be divided into three separate pieces of similar size. For example, solar cell 416 can include strips 422, 424, and 426. These strips can be arranged in such a way that adjacent strips are partially overlapped at the edges, similar to the ones shown in FIGS. 4A-4B. For simplicity of illustration, the electrode grids, including the finger lines and edge busbars, of the strips are not shown in FIG. 4C. In addition to the example shown in FIG. 4C, a solar roof tile can contain fewer or more cascaded strips, which can be of various shapes and size.

In some embodiments, multiple solar roof tiles, each encapsulating a cascaded string, can be assembled to obtain a multi-tile module. Inner-tile electrical coupling has been accomplished by overlapping corresponding edge busbars of adjacent strips. However, inter-tile electrical coupling within such a multi-tile module can be a challenge. Strain-relief connectors and long bussing strips have been used to facilitate inter-tile coupling. However, strain-relief connectors can be expensive, and arranging bussing strips after laying out the cascaded strings can be cumbersome. To facilitate low-cost, high-throughput manufacturing of the solar roof tiles, in some embodiments, metal strips can be pre-laid onto the back covers of the solar tiles, forming an embedded circuitry that can be similar to metal traces on a printed circuit board (PCB). More specifically, the embedded circuitry can be configured in such a way that it facilitates the electrical coupling among the multiple solar roof tiles within a multi-tile module.

Moreover, to facilitate electrical coupling between the embedded circuitry and an edge busbar situated on a front surface of a cascaded string, in some embodiments, a Si-based bridge electrode can be attached to the cascaded string. The Si-based bridge electrode can include a metallic layer covering its entire back surface and, optionally, a back edge busbar. By overlapping its edge (e.g., back edge busbar) to the front edge busbar of the cascaded string, the Si-based bridge electrode can turn itself into an electrode for the cascaded string, converting the forwardly facing electrode of the cascaded string to an electrode accessible from the back side of the cascaded string.

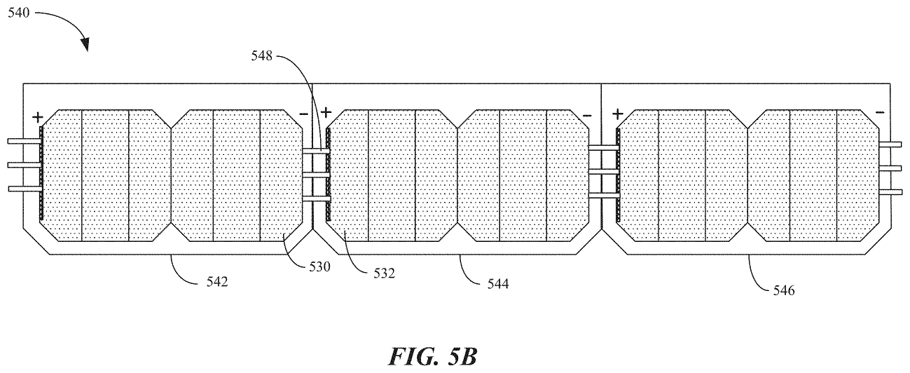

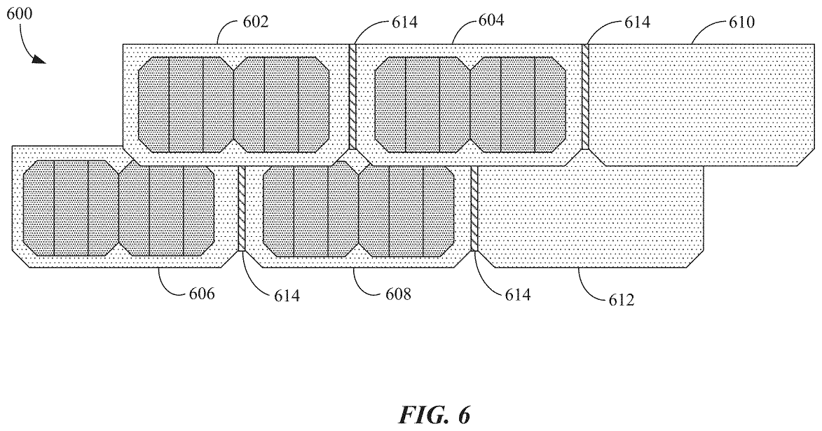

FIG. 5A shows a top view of an exemplary multi-tile module, according to one embodiment. Multi-tile module 600 can include PV roof tiles 502, 504, and 506 arranged side by side. Each PV roof tile can include six cascaded strips encapsulated between the front and back covers, meaning that busbars located at opposite edges of the cascaded string of strips have opposite polarities. For example, if the leftmost edge busbar of the strips in PV roof tile 502 has a positive polarity, then the rightmost edge busbar of the strips will have a negative polarity. Serial connections can be established among the tiles by electrically coupling busbars having opposite polarities, whereas parallel connections can be established among the tiles by electrically coupling busbars having the same polarity.

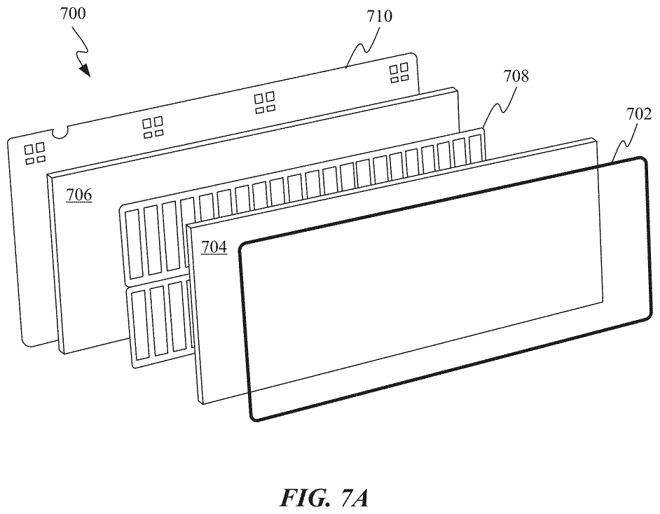

In the example shown in FIG. 5A, the PV roof tiles are arranged in such a way that their sun-facing sides have the same electrical polarity. As a result, the edge busbars of the same polarity will be on the same left or right edge. For example, the leftmost edge busbar of all PV roof tiles can have a positive polarity and the rightmost edge busbar of all PV roof tiles can have a negative polarity, or vice versa. In FIG. 6, the left edge busbars of all strips have a positive polarity (indicated by the “+” signs) and are located on the sun-facing (or front) surface of the strips, whereas the right edge busbars of all strips have a negative polarity (indicated by the “−” signs) and are located on the back surface. Depending on the design of the layer structure of the solar cell, the polarity and location of the edge busbars can be different from those shown in FIG. 5A.

A parallel connection among the tiles can be formed by electrically coupling all leftmost busbars together via metal tab 510 and all rightmost busbars together via metal tab 512. Metal tabs 510 and 512 are also known as connection buses and typically can be used for interconnecting individual solar cells or strings. A metal tab can be stamped, cut, or otherwise formed from conductive material, such as copper. Copper is a highly conductive and relatively low-cost connector material. However, other conductive materials such as silver, gold, or aluminum can be used. In particular, silver or gold can be used as a coating material to prevent oxidation of copper or aluminum. In some embodiments, alloys that have been heat-treated to have super-elastic properties can be used for all or part of the metal tab. Suitable alloys may include, for example, copper-zinc-aluminum (CuZnAl), copper-aluminum-nickel (CuAlNi), or copper-aluminum-beryllium (CuAlBe). In addition, the material of the metal tabs disclosed herein can be manipulated in whole or in part to alter mechanical properties. For example, all or part of metal tabs 510 and 512 can be forged (e.g., to increase strength), annealed (e.g., to increase ductility), and/or tempered (e.g. to increase surface hardness).

The coupling between a metal tab and a busbar can be facilitated by a specially designed strain-relief connector. In FIG. 5A, strain-relief connector 516 can be used to couple busbar 514 and metal tab 510. Such strain-relief connectors are needed due to the mismatch of the thermal expansion coefficients between metal (e.g., Cu) and silicon. As shown in FIG. 5A, the metal tabs (e.g., tabs 510 and 512) may cross paths with strain-relief connectors of opposite polarities. To prevent an electrical short of the photovoltaic strips, portions of the metal tabs and/or strain-relief connectors can be coated with an insulation film or wrapped with a sheet of insulation material.

In some embodiments, instead of parallelly coupling the tiles within a tile module using stamped metal tabs and strain-relief connectors as shown in FIG. 5A, one can also form serial coupling among the tiles. FIG. 5B shows the top view of an exemplary multi-tile module, according to one embodiment. Tile module 540 can include solar roof tiles 542, 544, and 546. Each tile can include a number (e.g., six) of cascaded solar cell strips arranged in a manner shown in FIGS. 4A and 4B. Furthermore, metal tabs can be used to interconnect photovoltaic strips enclosed in adjacent tiles. For example, metal tab 648 can connect the front of strip 632 with the back of strip 630, creating a serial coupling between strips 630 and 632. Although the example in FIG. 5B shows three metal tabs interconnecting the photovoltaic strips, other numbers of metal tabs can also be used. Furthermore, each solar roof tile can contain fewer or more cascaded strips, which can be of various shapes and sizes.

For simplicity of illustration, FIGS. 5A and 5B do not show the inter-tile spacers that provide support and facilitate mechanical and electrical coupling between adjacent tiles. Detailed descriptions of such inter-tile spacers can be found in U.S. Patent Publication US20190260328A1, entitled “INTER-TILE SUPPORT FOR SOLAR ROOF TILES,” the disclosure of which is incorporated herein by reference in its entirety.

### Color Matching in Solar Roof Tiles

As shown in FIG. 4C, FIG. 5A, and FIG. 5B, the photovoltaic structures and external electrodes encapsulated between the front and back covers can appear different than the background when viewed from the side of the transparent and colorless front cover. More specifically, the Si-based photovoltaic structures often appear to have a blue/purple hue. Although applying color onto the back cover can improve the color matching between the photovoltaic structures and the background, they cannot solve the problem of angle-dependence of color. In other words, the photovoltaic structures may appear to have different colors at different viewing angles, making color-matching difficult. Moreover, apart from solar roof tiles, a roof can sometimes include a certain number of “passive” or “dead” roof tiles, i.e., roof tiles that do not have embedded solar cells. These passive roof tiles can merely include the front and back covers and encapsulant sandwiched between the covers. The difference in appearance between the solar roof tiles and the passive roof tiles often results in a less pleasing aesthetic.

FIG. 6 shows a partial view of a roof having a number of solar roof tiles and passive roof tiles. In FIG. 6, roof 600 can include a number of roof tiles arranged in such a fashion that the lower edges of tiles in a top row overlap the upper edges of tiles in a bottom row, thus preventing water leakage. Moreover, the tiles are offset in such a manner that the gap between adjacent tiles in one row somewhat aligns with the center of a tile located in a different row. In the example shown in FIG. 6, tiles 602, 604, 606, and 608 are solar roof tiles, which can include photovoltaic structures encapsulated between front and back covers, and tiles 610 and 612 are passive roof tiles. As one can see from the drawing, the color contrast between the back covers and the photovoltaic structures can create a “picture frame” appearance of the solar roof tiles. In fact, the photovoltaic structures often appear to be “floating” above the colored back covers. Ideally, solar roof tiles 602-608 should have a similar appearance as passive roof tiles 610 and 612. Spacers 614 can fill gaps between adjacent tiles and prevent the passage of water between photovoltaic tiles 602-608. In some embodiments, spacers 614 can include electrical conductors that accommodate the passage of electricity and/or signals between adjacent photovoltaic tiles. In some embodiments, spacers 614 can define channels through which wires or similar conductors can carry the electricity and/or signals between the adjacent photovoltaic tiles.

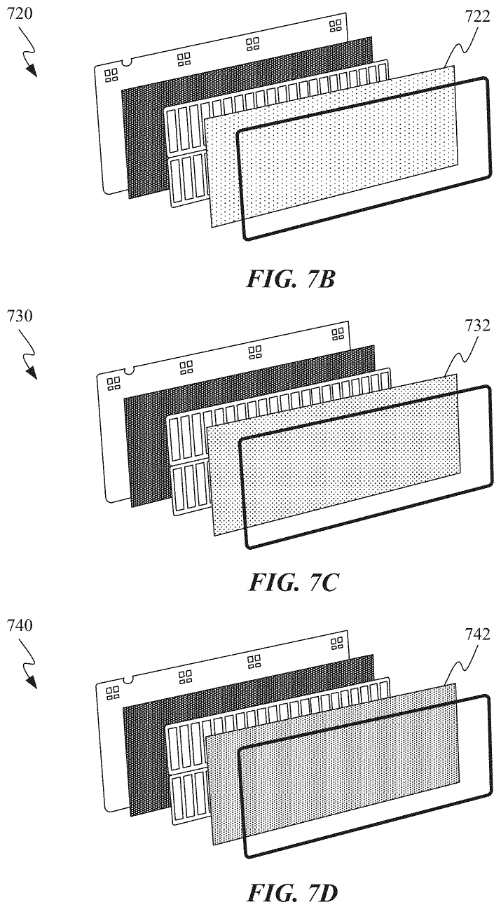

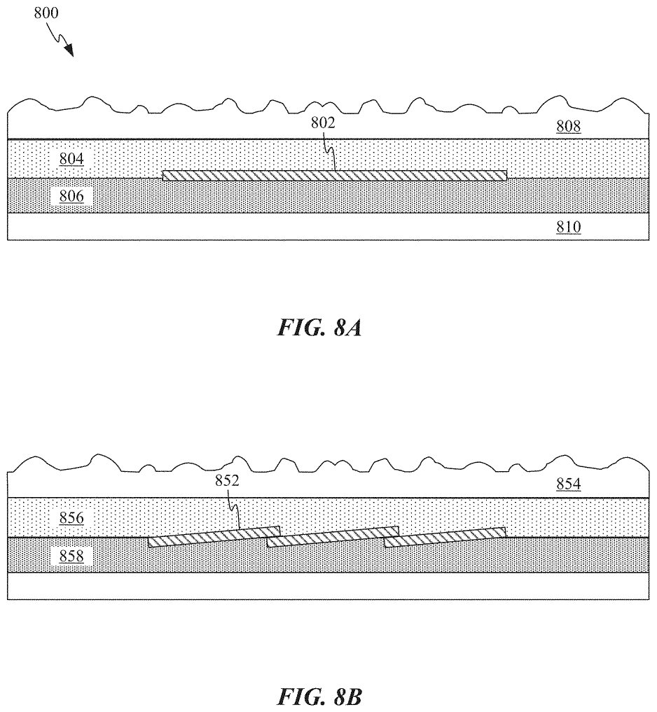

FIG. 7A shows an exploded view of an exemplary photovoltaic roof tile 700. Photovoltaic roof tile 700 includes a front glass cover 702. Front glass cover 702 can have a textured front and/or rear-facing surface to help diffuse light entering and exiting photovoltaic roof tile 700. Photovoltaic roof tile 700 also includes front encapsulant layer 704 and rear encapsulant layer 706. The encapsulant layers can be formed from optically transparent electrically insulating materials such polyvinyl butyral (PVB), thermoplastic polyolefin (TPO), ethylene vinyl acetate (EVA), and N,N′-diphenyl-N,N′-bis(3-methylphenyl)-1,1′-diphenyl-4,4′-diamine (TPD). In some embodiments, a small amount of inorganic pigment can be added to one or both of encapsulant layers 704 and 706 to give photovoltaic roof tile 700 a desired appearance without substantially impeding the flow of solar energy through front encapsulant layer 704. The pigment generally makes up less than 1% of encapsulant layer 704. In order to make encapsulant layer 706 opaque to light encapsulant layer 706 would generally be composed of two to five percent pigment. The inorganic pigment used should be substantially transparent to infrared light resulting in the addition of the pigment causing no more than a 10% reduction in the total amount of solar energy collected by photovoltaic roof tile 700. In some embodiments, a 20% reduction may result when brighter colored PV roof tiles are desired as the amount and/or type of pigment needed to get a brighter color can interfere more with incoming solar energy. For example, titanium oxide (e.g. TiO₂) or iron oxide (e.g. Fe₂O₃ or Fe₃O₄) based pigments can be infused within the front encapsulant layer to give the photovoltaic roof tiles gray and brown hues respectively. Additional pigment types include chromium oxide (e.g. Cr₂O₃) for green, cadmium for a yellow, orange or red and cobalt oxides for blue. Larger concentrations of, e.g., an iron oxide based pigment could also be used to achieve a red or orange color. While inorganic pigments are generally considered desirable for their stability, organic pigments can also be used as in certain configurations since they can be more transparent to infrared light than inorganic pigments.

An amount of the pigment infused into the material used to form front encapsulant layer 704 can vary based on the type of pigment used and upon the thickness of the front encapsulant layer. For example, higher concentrations of pigment could be used with relatively thinner front encapsulant layers. In some embodiments, a concentration of the pigment can make up about 0.5% of the material making up front encapsulant layer 704. A thickness of the front encapsulant layer with this concentration of pigment can be between 350 and 600 microns. In some embodiments a thickness of 450 and 500 microns can be desirable. Having a consistent thickness of front encapsulant layer 704 is desirable as variations in the thickness can result in undesired variations in color and overall thickness of the photovoltaic roof tiles. Furthermore, while a specific example of non-organic pigment is given the front encapsulant layer can alternatively be embedded with infrared-transparent nanoparticles or dyes to achieve a desired appearance. It should be appreciated that front encapsulant layers of up to 800 microns in thickness are possible with lower concentrations of the pigment within the encapsulant. A concentration of pigment within front encapsulant layer 704 will scale roughly linearly with the thickness of front encapsulant layer 704 to achieve a consistent color.

In some embodiments, different types of pigment are added to the front and back encapsulant layers. For example, rear encapsulant layer 706 can be infused with a pigment causing rear encapsulant layer 706 to have a blue or purple hue that matches a color of a solar cell 708, thereby preventing color variations between central regions of the photovoltaic tile occupied by solar cell 708 and peripheral regions of the photovoltaic roof tiles that extend beyond the area occupied by solar cell 708. A color of backsheet 710 can also contribute to an overall color of photovoltaic roof tile 700 when rear encapsulant layer 706 is not completely opaque to visible light. For example, a surface of backsheet 710 contacting rear encapsulant layer 706 can have a dark coloring to further darken an overall color of photovoltaic roof tile 700. It should be noted that while solar cell 708 is depicted as a unitary solar cell other configurations are possible. For example, any one of the solar cell configurations shown in FIGS. 2-4B are possible. It should be noted that solar cells may have minor color variance and the pigment used in the rear encapsulant layer to match the color of the solar cell may only match or correspond to one hue of the solar cell. In some embodiments, multiple different pigments can be non-homogenously mixed as will be described in greater detail below to include colors that match multiple hues of the solar cells.

FIGS. 7B-7D show how a concentration of pigment within the front encapsulant layer can allow variance in the cosmetic appearance of photovoltaic roof tiles 720, 730 and 740. While the singular term pigment is used it should be understood that the term pigment can refer to a mixture of multiple pigments. For example, a pigment can be formed from three to five different pigment mixes combined together to get a desired color. In particular, a front encapsulant layer 722 can have a lighter hue than a front encapsulant layer 732 and front encapsulant layer 732 can have a lighter hue than a front encapsulant layer 742. This variation can be accomplished by adjusting the amount of pigment within front encapsulant layers 722, 732 and 742. For example, using the previously given concentration of 0.5% as a starting point, the concentrations of pigment within front encapsulant layers 722, 732 and 742 can be 0.45%, 0.5% and 0.55% respectively. In some embodiments, a smaller amount of variation can be applied using concentrations of 0.475%, 0.5% and 0.525%. While an example of only three different concentration variations are given here it should be appreciated that any number of concentration variations are possible. For example, it may be desirable to have a greater number of variations for particular colors. It should be appreciated that the pigmented photovoltaic roof tile configurations can vary from one in which there are no variations in pigment to ten or more variations in pigment. Variations in pigment concentration will normally be no more than 10% as greater concentration variations of the pigment could result in an undesirable drop in performance of the photovoltaic roof tiles or undesirable aesthetic.

In some embodiments, photovoltaic roof tiles can be combined into a photovoltaic module that includes two or more photovoltaic roof tiles similar to the configurations shown in FIGS. 5A and 5B. In such a photovoltaic module, photovoltaic roof tiles with different concentrations of pigment can be attached together. Prefabricating the photovoltaic roof tiles into modules can help reduce an amount of labor needed to install the photovoltaic roof tiles on a roof top. Providing installers with photovoltaic modules with multiple different color combinations helps the installers produce a roof with a cosmetically pleasing randomized appearance.

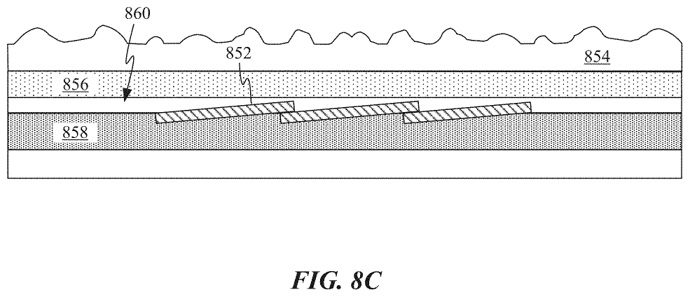

FIGS. 8A-8B show side views of exemplary photovoltaic roof tiles. FIG. 8A shows a solar cell 802 embedded within front encapsulant layer 804 and rear encapsulant layer 806. Front glass cover 808 is placed atop front encapsulant layer 804 and is textured to help diffuse light entering in to and exiting out of front glass cover 808. An appearance of front encapsulant layer 804 can be achieved by incorporating a single pigment or a non-homogenous mixture of multiple pigments into front encapsulant layer 804. The non-homogenous mixture of multiple pigments can be used to achieve a more natural variation in a cosmetic appearance of photovoltaic roof tiles.

FIG. 8B shows a cascaded solar cell embedded by front encapsulant layer 854 and rear encapsulant layer 856 sharing features of the cascaded solar cells described in relation to FIGS. 4A and 4B. As can be seen in FIG. 8B, some portions of cascaded solar cell 852 are slightly closer to front glass cover 854 than other portions. This results in a thickness of front encapsulant layer varying across a sun-facing surface of the cascaded solar cell, which can in turn result in slight color variations of the photovoltaic roof tile above portions of the photovoltaic roof tile occupied by cascaded solar cell 852. In some embodiments, the textured surface of front glass cover 854 can help to attenuate the perception of this color variance. The perception issues resulting from the overlapping solar cells can also be attenuated by increasing a thickness of front encapsulant layer 856 relative to the amount of height variation resulting from the overlapping solar cell configuration. A thickness of the front encapsulant layer could be in the 600-800 micron range to account for the thickness variation inherent to a cascaded solar cell configuration.

FIG. 8C shows how a clear encapsulant layer 860 could be added between front encapsulant layer 856 and the sun-facing surface of solar cells 852. This configuration would allow a uniform amount of pigment to be placed in front of each portion of solar cells 852 independent of the geometry of the solar cell overlap. In some embodiments, clear encapsulant could be sized to be just thick enough to prevent thickness variation in front encapsulant layer 856. In some embodiments, a thickness of clear encapsulant layer 860 could be about the same as front encapsulant layer 856. In one particular embodiment, clear encapsulant layer 860 and front encapsulant layer 856 could each be about 450 microns thick.

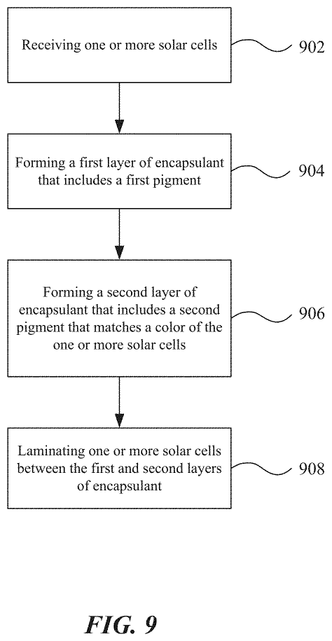

FIG. 9 shows a flow chart illustrating a manufacturing process for a photovoltaic roof tile. At 902 one or more solar cells are received. In some embodiments, a color of the solar cells is measured to be sure the color of the solar cells are consistent with the expected color. The solar cells can be arranged in any of the various configurations depicted in FIGS. 2-4B. At 904, encapsulant material, such as EVA, can be mixed with a first pigment to form a first layer of encapsulant. The first pigment can take the form a mixture of different pigments measured carefully to give the photovoltaic roof tile a desired cosmetic color appearance. For example, a first iron oxide pigment could include a particular mix of Fe₂O₃ and Fe₃O₄ pigments and potentially other iron oxide based pigments. Alternatively, a dye or nanoparticles can be mixed with encapsulant material to form the first layer of encapsulant. At 906, a second layer of encapsulant can be formed using encapsulant material and a second pigment. The second pigment can be added to the encapsulant in an amount that causes the second layer of encapsulant to match the measured color of the solar cells. In some embodiments, the color of the second layer of encapsulant can be tuned to match an average color of a large group of solar cells, while in other embodiments, the color of the second layer of encapsulant can be tuned to match a particular solar cell or small group of solar cells. At 908, the one or more solar cells can be laminated between the firsts and second layers of encapsulant. The lamination process will also generally include sandwiching the encapsulant layers between a front glass cover and a backsheet or back glass cover. It should be noted that an amount of pressure and heat applied during the lamination process can affect the overall color of the photovoltaic roof tile since too much pressure or heat could result in an unwanted variation in the thickness of one or both of the first and second layers of encapsulant. This variation could result in a photovoltaic roof tile that has to be disposed of due to having too much color variance. Completed photovoltaic roof tiles can be subsequently pre-assembled into photovoltaic roof tile modules. In some embodiments, the amount of pigment added to each of the photovoltaic roof tiles making up the module can vary by between five and ten percent.

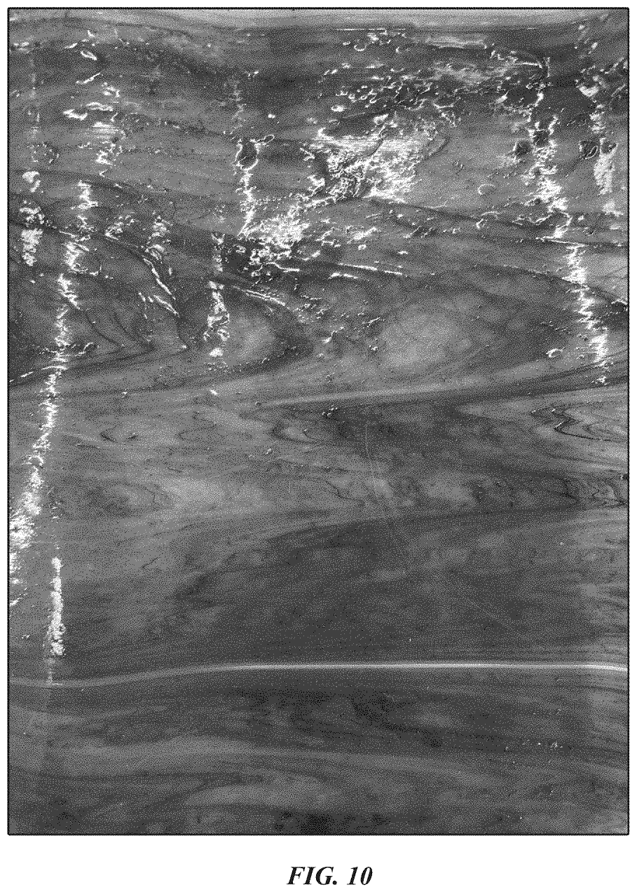

FIG. 10 shows a picture of an exemplary non-homogenous mixture of pigments within encapsulant material. This type of mixture of first and second pigment types can be achieved by selecting pigment masterbatches having different properties. Pigment masterbatches are typically a concentrated mixture of pigments and/or additives encapsulated during a heating process into a carrier resin which is then cooled and cut into a granular shape. The pigment masterbatches are selected to have different viscosities. In some embodiments, the viscosity of pigment masterbatches is varied by adjusting the makeup of the carrier resin used to form the pigment masterbatches.

In contrast, industry practice is to minimize differences in pigment masterbatch viscosities in order to avoid color non-uniformity. When the encapsulant material and pigment masterbatches of different viscosity are mixed together at a controlled mixing temperature the difference or differences in viscosities at that mixing temperature results in the non-homogenous mixture of colors depicted in FIG. 10. In some embodiments, the pigments can be mixed in a particular way in order to distribute the first and second pigments in a desirable pattern. For example, a mixture of encapsulant and pigment masterbatches can be mixed in an extruder at a predetermined speed to achieve a desired pattern prior to initiating an extrusion operation. The pattern generally depends at least upon how different the viscosities are and the techniques used to mix the materials together. In some embodiments, a viscosity of the pigment masterbatches can also be selected to differ from a viscosity of the encapsulant so that portions of the encapsulant can remain free of both all of the pigments. Regardless of composition, once a desired non-homogenous mixture is achieved, the material can be flowed through the extruder to form an encapsulant layer with the desired distribution and patterning of pigments. Once the encapsulant and pigments cool the relative positions of the first and second pigments within the encapsulant layer is fixed. It should be appreciated that while FIG. 10 depicts a mixture of two pigments that in some embodiments, three or more pigments may be mixed together, where a subset of the multiple pigment masterbatches has a different viscosity than the other pigment masterbatches to achieve a desired non-homogenous mixture of pigments within the encapsulant layer.

In some embodiments, a non-homogenous mixture of pigments can be achieved by modifying an extrusion process used to mix the pigments together when forming the encapsulant layers. In particular, the extrusion process can be adjusted to reduce the residence time of the encapsulant and pigments within the extruder and/or reduce the intensity of mixing within the extruder. The residence time reduction is achieved by speeding up the extruder and the mixing intensity reduction is achieved by careful selection of extruder screw elements. For example, slots can be cut around a flight tip of the screw element to increase leakage flow through the extruder. In some embodiments, adjustments to the extrusion process can be combined with deliberate variations in the viscosity of the pigment masterbatches to achieve the desired non-homogenous mixture of pigments.

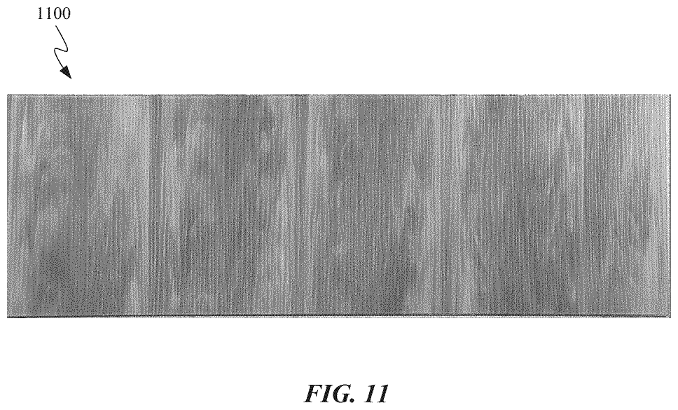

FIG. 11 shows a distribution of multiple pigments within a photovoltaic roof tile 1100. While the image of photovoltaic roof tile 1100 is shown in black and white, the shades of gray represent different shades of brown. However, it should be appreciated that different pigment colors and different ratios of pigments are possible. For example, in some embodiments, only a small amount of a second pigment could be mixed with a first pigment to provide only minor color variations in a photovoltaic roof tile. A smaller amount of the second pigment might also be more desirable where the second pigment is less transparent to visible or infrared light than the first pigment. In some embodiments, different photovoltaic roof tiles or roof tile modules may include different ratios of different pigments so a homeowner's roof has a greater amount of color variation.

The foregoing descriptions of various embodiments have been presented only for purposes of illustration and description. They are not intended to be exhaustive or to limit the present system to the forms disclosed. Accordingly, many modifications and variations will be apparent to practitioners skilled in the art. Additionally, the above disclosure is not intended to limit the present system.

What is claimed is:

1. A photovoltaic roof tile module, comprising:
a photovoltaic roof tile, comprising:
a front glass cover;
a front encapsulant layer doped with a first pigment;
a back encapsulant layer doped with a second pigment different than the first pigment that corresponds to a color of the plurality of solar cells; and
a plurality of solar cells positioned between the front and back encapsulant layers.

2. The photovoltaic roof tile module as recited in claim 1, wherein the photovoltaic roof tile is a first photovoltaic roof tile and the photovoltaic roof tile module further comprises a second photovoltaic roof tile electrically and mechanically coupled to the first photovoltaic roof tile, wherein the front encapsulant layer of the first photovoltaic roof tile has a larger amount of the first pigment than a front encapsulant layer of the second photovoltaic roof tile.

3. The photovoltaic roof tile module as recited in claim 2, further comprising a third photovoltaic roof tile electrically and mechanically coupled to the second photovoltaic roof tile, wherein a front encapsulant layer of the third photovoltaic roof tile has a larger amount of the first pigment than the front encapsulant layer of the second photovoltaic roof tile.

4. The photovoltaic roof tile module as recited in claim 2, wherein the front encapsulant layer of the first photovoltaic roof tile has five to ten percent more of the first pigment than the front encapsulant layer of the second photovoltaic roof tile.

5. The photovoltaic roof tile module of claim 1, wherein the plurality of solar cells comprises a first edge busbar positioned near an edge of a first surface and a second edge busbar positioned near an opposite edge of a second surface, and wherein the plurality of solar cells are arranged in such a way that the first edge busbar of a first solar cell overlaps the second edge busbar of an adjacent solar cell, thereby resulting in the plurality of solar cells forming a serially coupled string.

6. The photovoltaic roof tile module of claim 4, further comprising a clear encapsulant layer disposed between the plurality of solar cells and the front encapsulant layer.

7. The photovoltaic roof tile module of claim 1, wherein the first pigment is an iron oxide based pigment or a titanium oxide based pigment.

8. The photovoltaic roof tile module of claim 1, wherein the front encapsulant layer is between 350 and 800 microns thick.

9. The photovoltaic roof tile module of claim 1, wherein the first pigment is evenly distributed within the front encapsulant layer and makes up less than 1% of the material making up the front encapsulant layer.

10. The photovoltaic roof tile module of claim 1, wherein the first encapsulant layer is doped with a third pigment mixed non-homogenously with the first pigment.

11. A photovoltaic roof tile, comprising:
a front glass cover;
a front encapsulant layer doped with a first pigment;
a plurality of solar cells; and
a back encapsulant layer doped with a second pigment different than the first pigment that corresponds to a color of the plurality of solar cells.

12. The photovoltaic roof tile of claim 11, wherein a respective solar cell comprises a first edge busbar positioned near an edge of a first surface and a second edge busbar positioned near an opposite edge of a second surface, and wherein the plurality of solar cells are arranged in such a way that the first edge busbar of a first solar cell overlaps the second edge busbar of an adjacent solar cell, thereby resulting in the plurality of solar cells forming a serially coupled string.

13. The photovoltaic roof tile of claim 12, further comprising a clear encapsulant layer disposed between the front encapsulant layer and the plurality of solar cells.

14. The photovoltaic roof tile of claim 12, wherein the first encapsulant layer conforms to the overlapping geometry of the plurality of solar cells.

15. The photovoltaic roof tile of claim 11, wherein the first pigment is evenly distributed throughout the front encapsulant layer.

16. The photovoltaic roof tile of claim 11, wherein the front encapsulant layer is between 350 microns and 800 microns.

17. The photovoltaic roof tile of claim 11, wherein the first pigment has a brown hue and the second pigment has a blue or purple hue.

18. The photovoltaic roof tile of claim 11, wherein the front encapsulant layer is also doped with a third pigment that is mixed non-homogenously with the first pigment.

19. The photovoltaic roof tile of claim 11, further comprising a backsheet having a color that cooperates with a color of the back encapsulant layer to match a color of the plurality of solar cells.

20. The photovoltaic roof tile of claim 11, wherein the back encapsulant layer is opaque to visible light.
